(19) United States
(12) Patent Application Publication
(10) Pub. No.: US 2010/0078712 A1
(43) Pub. Date: Apr. 1, 2010

(54) SEMICONDUCTOR DEVICE AND METHOD OF MANUFACTURING THE SAME

(75) Inventors: Yoshinori IKEBUCHI, Tokyo (JP); Kiyonori OYU, Tokyo (JP); Yoshihiro TAKAISHI, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/561,713

(22) Filed: Sep. 17, 2009

(30) Foreign Application Priority Data
Sep. 26, 2008 (JP) 2008-248721

(51) Int. Cl. H01L 27/06; H01L 21/336

(52) U.S. Cl. 257/329; 438/268; 257/E27.026; 438/586; 257/E21.41

(57) ABSTRACT

A semiconductor device includes a first semiconductor pillar, a first gate insulating film, a gate electrode, and a first contact. The first semiconductor pillar extends upwardly from a semiconductor substrate. The first gate insulating film covers side surfaces of the first semiconductor pillar. The gate electrode covers the first gate insulating film. The first gate insulating film insulates the gate electrode from the first semiconductor pillar. The first contact partially overlaps, in plane view, the first semiconductor pillar and the gate electrode. The first contact includes a silicon layer having a top level which is higher than a top level of the gate electrode.

### BACKGROUND OF THE INVENTION

1. Field of the Invention

The present invention relates to a semiconductor device and a method of manufacturing the same.

Priority is claimed on Japanese Patent Application No. 2008-248721, filed Sep. 26, 2008, the content of which is incorporated herein by reference.

2. Description of the Related Art

Higher integration and higher performance of semiconductor devices are mostly implemented by miniaturization of transistors. Recently, it has been more difficult to miniaturize transistors. Three-dimensional structured transistors have been considered for miniaturization of transistors.

For example, vertical transistors have been proposed as a three-dimensional transistor. Japanese Patent, Laid-Open Publication No. H06-21467 discloses a method of forming a contact plug that is made of polysilicon and connectable to a gate electrode.

Specifically, in a vertical transistor disclosed in this document, the gate electrode surrounds a semiconductor pillar extending perpendicularly to a substrate. To form the contact plug made of polysilicon, a gate insulating film is formed on a sidewall of the semiconductor pillar to be used for lifting the gate. Then, a polysilicon film is formed over the entire surface, and then etched by dry etching. Thus, the contact plug is formed. Then, an inter-layer insulating film is formed to cover the gate electrode. Then, a contact plug connectable to the gate electrode is formed in the inter-layer insulating film.

However, even in the case of using the vertical transistor as disclosed in the above document, a thick gate electrode cannot be formed due to a requirement to reduce chip size. Consequently, if planarly viewed, the contact plug overlaps the gate lifting semiconductor pillar, the gate insulating film, and the gate electrode. For this reason, a bottom surface and a side surface of the contact plug are very close to the gate insulating film. If a metal silicide for reducing resistance is formed immediately below the contact plug, the metal silicide reaches the gate insulating film, thereby causing an erosion breakdown of the gate insulating film. Consequently, the gate electrode and the semiconductor pillar including a silicon substrate short-circuit. Hereinafter, conventional problems are explained with reference to FIG. 6 illustrating conventional problems.

In a conventional vertical transistor 150 as shown in FIG. 6, a contact plug 115 overlaps the gate lifting semiconductor pillar 105, the gate insulating film 107, and the gate electrode 108. Consequently, bottom and side surfaces of the contact plug 115 are very close to the gate insulating film 107. Therefore, a silicide layer 119, made of metal silicide formed by siliciding a metal forming a bottom portion of the contact plug 115 and polysilicon forming the gate electrode 108, reaches the gate insulating film 107, and thereby might cause an erosion breakdown of the gate insulating film 107.

### SUMMARY

In one embodiment, there is provided a semiconductor device that includes a first semiconductor pillar, a first gate insulating film, a gate electrode, and a first contact. The first semiconductor pillar extends upwardly from a semiconductor substrate. The first gate insulating film covers side surfaces of the first semiconductor pillar. The gate electrode covers the first gate insulating film. The first gate insulating film insulates the gate electrode from the first semiconductor pillar. The first contact partially overlaps, in plane view, the first semiconductor pillar and the gate electrode. The first contact includes a silicon layer having a top level which is higher than a top level of the gate electrode.

In another embodiment, there is provided a method of manufacturing a semiconductor device. The method includes the following processes. First and second semiconductor pillars are formed to extend upwardly from a semiconductor substrate. First and second gate insulating films are formed to cover side surfaces of the first and second semiconductor pillars, respectively. A gate electrode is formed to surround a combination of the first semiconductor pillar and the first gate insulating film, and a combination of the second semiconductor pillar and the second gate insulating film. A first contact is formed to partially overlap, in plane view, the first semiconductor pillar and the gate electrode. A silicon layer is formed in the first contact to have a top level which is higher than a top level of the gate electrode.

According to the semiconductor device, the silicon layer having the top level higher than the top level of the gate electrode is provided. Accordingly, the bottom portion of the contact plug on the silicon layer is distanced from the gate insulating film. Therefore, when the silicide layer is formed below the contact plug, a breakdown of the gate insulating film due to a silicide reaction can be prevented.

According to the method of manufacturing the semiconductor device, the silicon layer is formed by selective epitaxial growth from the upper surface of the gate electrode. Accordingly, the gate electrode and the silicon layer are integrated, thereby preventing an increase in electric resistance.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view illustrating a semiconductor device according to a first embodiment of the present invention;

FIG. 2 is a plane view illustrating the semiconductor device according to the first embodiment;

FIGS. 3 and 4 are cross-sectional views illustrating a method of manufacturing the semiconductor device according to the first embodiment;

FIG. 5 is a cross-sectional view illustrating a semiconductor device according to a second embodiment of the present invention; and

FIG. 6 is a cross-sectional view illustrating a semiconductor device including a conventional vertical transistor.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

### First Embodiment

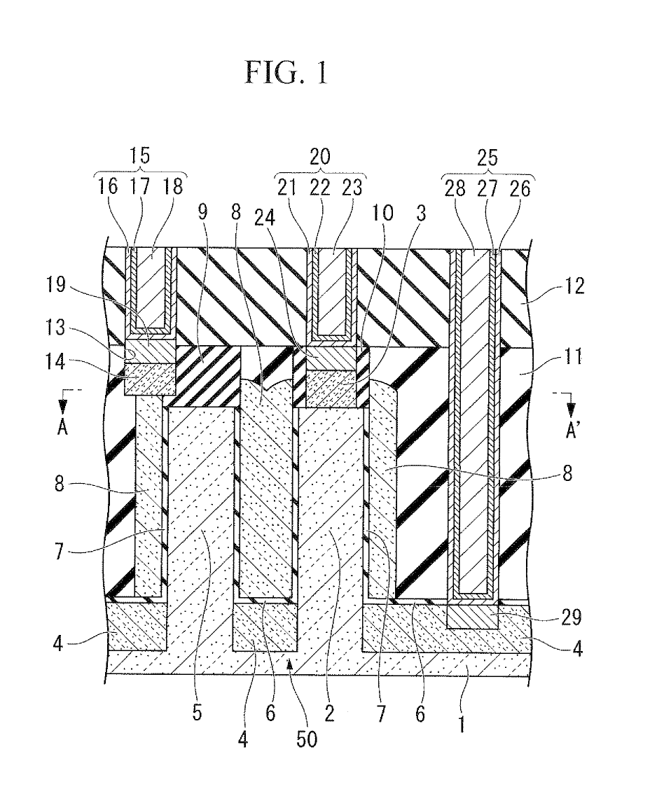

FIG. 1 is a cross-sectional view illustrating a semiconductor device according to a first embodiment of the present invention. A silicon pillar 2 is formed on a silicon substrate 1. The silicon pillar 2 is a pillar-shaped semiconductor layer that will be a channel portion of the vertical transistor 50.

An impurity diffusion layer is formed on each of upper and lower portions of the silicon pillar 2. For example, in the first embodiment, an upper diffusion layer 3 formed immediately above the silicon pillar 2 is a source diffusion layer, and a lower diffusion layer 4 formed below the silicon pillar 2 is a drain diffusion layer. A center portion of the silicon pillar 2 between the upper and lower diffusion layers 3 and 4 is a channel portion. The upper and lower diffusion layers 3 and 4 may be drain and source diffusion layers, respectively.

The upper diffusion layer 3 is formed by an impurity being diffused in a silicon layer formed by selective epitaxial growth from an upper surface of the silicon pillar 2.

A silicon pillar 5 for supplying power to a gate electrode is formed around the silicon pillar 2. The silicon pillars 2 and 5 are formed by etching a surface of the silicon substrate 1. The silicon pillar 5 is a pillar-shaped semiconductor layer protruding upwardly from the surface of the silicon substrate 1. The silicon pillar 5 serves as a protrusion layer for making the gate electrode 8 higher to reduce a distance between the gate electrode 8 and upper metal wires (not shown).

An oxide film (insulating film) 6 is formed to cover the surface of the silicon substrate 1 excluding regions of the silicon pillars 2 and 5. The lower diffusion layer 4 is formed immediately below the oxide film 6 and insulates the lower diffusion layer 4 from the gate electrode 8. The lower diffusion layer 4 electrically connects the silicon pillars 2 and 5.

A gate insulating film 7 is formed to cover side surfaces of each of the silicon pillars 2 and 5. A gate electrode 8 is formed to surround the silicon pillars 2 and 5 while the gate insulating film 7 insulates the silicon pillars 2 and 5 from the gate electrode 8. The gate insulating film 7 covers side surfaces of the silicon pillars 2 and 5 and connects to the oxide film 6. The channel portion of the silicon pillar 2, the upper diffusion layer 3, and the lower diffusion layer 4 are electrically insulated from the gate electrode 8 by the gate insulating film 7 and the oxide film 6.

The gate electrode 8 is made of poly-crystal silicon (hereinafter, “polysilicon”), and covers the silicon pillars 2 and 5 so as to completely fill a gap between the silicon pillars 2 and 5.

A nitride film 9 is formed to cover the upper surface of the silicon pillar 5. The nitride film 9 serves as a protrusion layer for making the silicon pillar 5 and the gate electrode 8 higher to reduce a distance between the gate electrode 8 and the upper metal wires (not shown).

A sidewall nitride film 10 is formed on the silicon pillar 2 to surround the upper diffusion layer 3 and electrically insulates the gate electrode 8 from the upper diffusion layer 3. A first inter-layer insulating film 11 is formed to cover the oxide film 6, the gate electrode 8, the nitride film 9, and the sidewall nitride film 10. A second inter-layer insulating film 12 is formed to cover the nitride film 9, the sidewall nitride film 10, and the first inter-layer insulating film 11. Metal wires (not shown) are formed on the second inter-layer insulating film 12.

A contact hole 13 penetrates the first and second inter-layer insulating films 11 and 12 and a part of the nitride film 9, and overlaps the gate electrode 8 in plane view parallel with the silicon substrate 1. The level of a bottom surface of the contact hole 13 is higher than the level of an upper surface of the silicon pillar 5 to prevent the contact hole 13 from directly contacting the gate insulating film 7.

A gate lifting polysilicon layer (embedded silicon layer, epitaxial growth layer) 14 is formed in a bottom portion of the contact hole 13. The gate lifting polysilicon layer 14 is formed by filling polysilicon from the level of the bottom surface of the contact hole 13 up to a level higher than the level of the upper surface of the gate electrode 8. This polysilicon layer is formed by selective epitaxial growth from the surface of the gate electrode 8 facing the contact hole 13. Thus, the gate electrode 8 and the gate lifting polysilicon layer 14 have an integrated structure that is lifted higher than the level of the upper surface of the gate electrode 8.

A contact plug 15 is formed on the gate lifting polysilicon layer 14 by embedding a metal into the contact hole 13. Specifically, a titanium layer 16, a titanium nitride layer 17, and a tungsten layer 18 are deposited so that the titanium layer 16 covers the bottom and side surfaces of the contact plug 15, the titanium nitride layer 17 covers the bottom and side surfaces of the titanium layer 16, and the tungsten layer 18 covers the bottom and side surfaces of the titanium nitride layer 17. A titanium silicide layer (silicide layer) 19 is formed between the titanium layer 16 and the gate lifting polysilicon layer 14. The titanium silicide layer 19 is positioned at a level higher than the top level of the gate insulating film 7. The contact plug 15 connects to the gate electrode 8 through the titanium silicide layer 19 and the gate lifting polysilicon layer 14.

A contact plug 20 penetrates the second inter-layer insulating film 12 and connects to the upper diffusion layer 3. The contact plug 20 is formed by depositing a titanium layer 21, a titanium nitride layer 22, and a tungsten layer 23 so that the titanium layer 21 covers the bottom and side surfaces of the contact plug 20, the titanium nitride layer 22 covers the bottom and side surfaces of the titanium layer 21, and the tungsten layer 23 covers the bottom and side surfaces of the titanium nitride layer 22. A titan silicide layer 24 is formed between the titanium layer 21 and the upper diffusion layer 3. The sidewall nitride film 10 electrically insulates the titanium silicide 24 from the gate electrode 8.

A contact plug 25 penetrates the first and second inter-layer insulating films 11 and 12 and the oxide film 6, and connects to the lower diffusion layer 4. The contact plug 25 is formed by depositing a titanium layer 26, a titanium nitride layer 27, and a tungsten layer 28 so that the titanium layer 26 covers the bottom and side surfaces of the contact plug 25, the titanium nitride layer 27 covers the bottom and side surfaces of the titanium layer 26, and the tungsten layer 28 covers the bottom and side surfaces of the titanium nitride layer 27. The contact plug 25 is formed in the first and second inter-layer insulating films 11 and 12 where the gate electrode 8 is not formed.

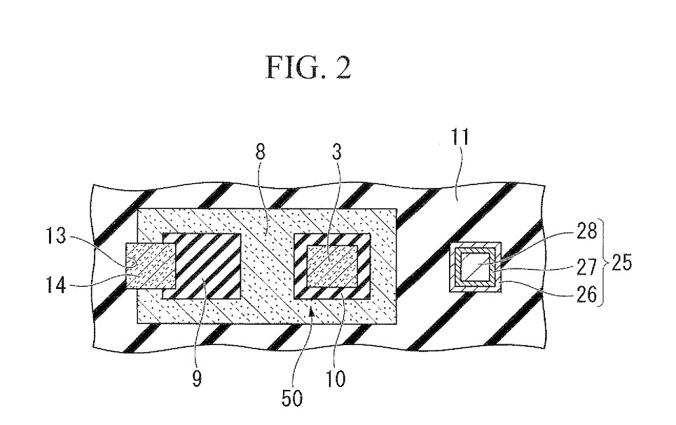

FIG. 2 is a plane view illustrating the semiconductor device according to the first embodiment. The upper diffusion layer 3, the sidewall nitride film 10, and the contact plug 20 are formed above the silicon pillar 2. The silicon pillar 2, the upper diffusion layer 3, the sidewall nitride film 10, and the contact plug 20 overlap one another in the same plane view parallel with the silicon substrate 1.

The silicon pillar 5 is formed on the left side of the silicon pillar 2. The nitride film 9, the gate lifting polysilicon 14, and the contact plug 15 which are rectangular if planarly viewed are formed above the silicon pillar 5. The silicon pillar 5 and the nitride film 9 overlap each other in the same plane view.

The gate lifting polysilicon layer 14 and the contact plug 15 partially overlap the silicon pillar 5. The left side of the gate lifting polysilicon layer 14 (opposite to the side of the silicon pillar 2) slightly deviates from the region of the silicon pillar 5. The deviated portion of the gate lifting polysilicon 14 connects to the gate electrode 8 covering the side surface of the nitride film 9.

The contact plug 25 which is rectangular if planarly viewed is formed on the right side of the silicon pillar 2 (opposite to the side of the silicon pillar 5).

Although one rectangular silicon pillar 2 is shown in FIG. 2, the shape, the number, and the position of the silicon pillar 2 are not limited thereto. For example, the silicon pillar 2 may be a circle or polygon other than a rectangle if planarly viewed. When multiple silicon pillars 2 are formed, the silicon pillars 2 are arranged in a honey comb manner for a closest packing, thereby achieving a more miniaturized and higher integrated semiconductor device. The silicon pillar 5 is a protrusion layer for making the gate electrode 8 higher to reduce a distance between the gate electrode 8 and the upper metal wires (not shown), and the size and the shape of the silicon pillar 5 are not particularly limited.

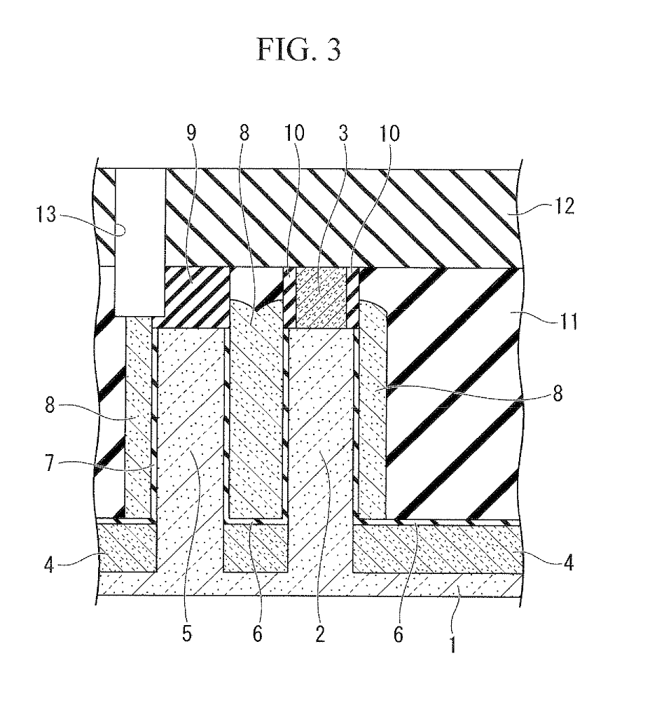

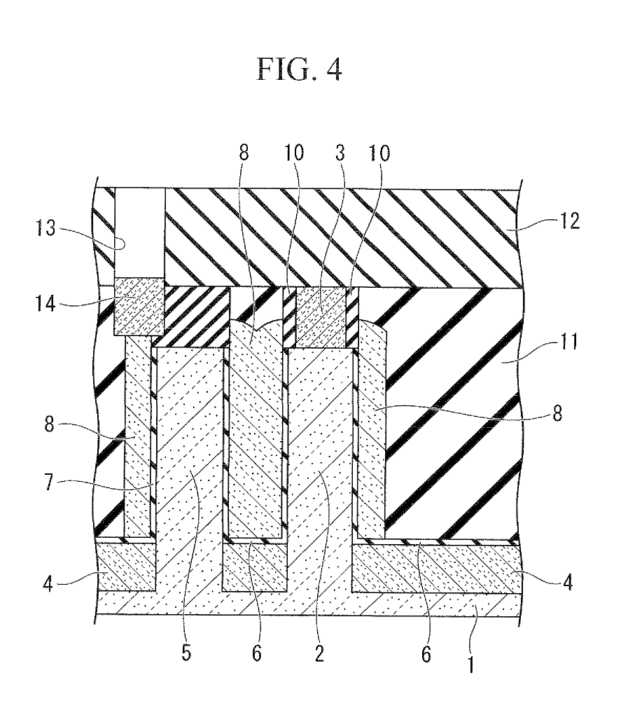

FIGS. 3 and 4 are cross-sectional views illustrating a method of manufacturing the semiconductor device according to the first embodiment.

Firstly, an oxide film having a thickness of 10 nm and a mask nitride film having a thickness of 120 nm are formed on the silicon substrate 1.

Then, the oxide film and the mask nitride film are patterned by known photolithography and dry etching. Then, the silicon substrate 1 is etched by nearly equal to 150 nm using the mask nitride film as a mask. Thus, the silicon pillar 2 that will be a channel portion of a unit transistor and the silicon pillar 5 for connecting the gate electrode 8 to metal wires on an upper layer are formed. The layout of the silicon pillars 2 and 5 are as shown in FIG. 2. The size of the silicon pillar 5 for lifting the gate electrode 8 is not limited, and may be different from the size of the silicon pillar 2 that will be the channel portion.

Then, the side surfaces of the silicon pillars 2 and 5 are oxidized by nearly equal to 5 nm to form a nitride film having a thickness of 20 nm. Then, the entire surface is etched to form a sidewall nitride film covering side surfaces of the silicon pillars 2 and 5 and the mask nitride film.

Then, silicon oxidation is carried out to form the oxide film 6 on the silicon substrate excluding the regions of the silicon pillars. At this time, the side surfaces and the upper surface of the silicon pillars 2 and 5 are covered by the nitride film and therefore not oxidized.

Then, ion-implantation of an impurity, such as arsenic, is carried out in the case of an N-type transistor to form the diffusion layer 4 below the silicon pillar 2. At this time, an impurity diffusion layer is not formed on the silicon pillars 2 and 5 since the mask nitride film having a thickness of nearly equal to 100 nm which is thicker than the oxide film 6 having the thickness of 30 nm is formed to cover the upper surfaces of the silicon pillars 2 and 5.

Then, the sidewall nitride film, and the oxide film formed on the side surface of the silicon pillar 2 are removed.

Then, the gate insulating film 7 is formed to cover the side surfaces of the silicon pillars 2 and 5. If the gate insulating film 7 is a silicon oxide film, the silicon oxide film has a thickness of nearly equal to 3 nm. Then, a polysilicon film having a thickness of 20 nm which will be a gate electrode is formed over the entire surface, and then etched so that the gate electrode 8 is formed to cover only the side surfaces of the silicon pillars 2 and 5.

Then, the first inter-layer insulating film 11 is formed. Then, the first inter-layer insulating film 11 is planarized by a known CMP (Chemical Mechanical Polishing) technique until the mask nitride film appears. Then, the mask oxide film is formed.

Then, only the mask oxide film covering the silicon pillar 2 is removed by known photolithography and etching. After the mask oxide film is removed, the mask nitride film appears.

Then, the shown mask nitride film above the silicon pillar 2 is removed.

Then, the nitride film having a thickness of 10 nm is formed, and then is etched to form the sidewall nitride film 10 on the opening above the silicon pillar 2. At the time of forming the sidewall nitride film 10, an oxide film (not shown) that has been formed above the silicon pillar 2 is also etched, and the upper surface of the silicon pillar 2 appears.

Then, a silicon layer is selectively formed on the upper surface of the silicon pillar 2 by selective epitaxial growth. Then, ion implantation of an impurity, such as arsenic in the case of an N-type transistor, is carried out to form the upper diffusion layer 3 immediately above the silicon pillar 2. Then, the entire surface is planarized, and then the second inter-layer insulating film 12 is formed.

Then, the contact hole 13 is formed with respect to the silicon pillar 5 by known photolithography and dry etching (reactive ion etching), as shown in FIG. 3. For example, the reactive ion etching is carried out by providing CHF₃ gas, O₂ gas, and Ar gas with the total flow volume of 250 sccm and at pressure of 25 mTorr. The position of the contact hole 13 is slightly deviated from the center of the silicon pillar 5, as shown in FIG. 2. At this time, since the nitride film remains on the silicon pillar 5, the etching is carried out not down to the upper level of the silicon pillar 5, but down to the top level of the gate electrode 8.

Then, selective polysilicon growth is carried out from the upper surface of the gate electrode 8 made of polysilicon to form the gate lifting polysilicon 14, as shown in FIG. 4. The selective polysilicon growth is carried out at 780° C., at pressure of 10 Torr, by providing DCS of 70 sccm, HCL of 40 sccm, and H₂ of 19 slm.

Then, a contact hole is formed for each of the silicon pillar 2 and the lower diffusion layer 4. Then, a metal made of W/TiN/Ti is embedded into each contact hole to form the titanium silicide layers 19, 24, and 29. Then, the contact plugs 15, 20, and 25 are formed with respect to the silicon pillar 5, the silicon pillar 2, and the lower diffusion layer 4, respectively. Thus, the semiconductor device is complete.

As explained above, according to the semiconductor device of the first embodiment, the gate lifting polysilicon layer 14 is formed in the contact hole 13 up to the level higher than the level of the upper surface of the gate electrode 8. For this reason, a distance between the gate insulating film 7 and a boundary between the titanium silicide layer 19 and the unreacted-polysilicon layer 14 becomes larger. Therefore, an erosion breakdown of the gate insulating film 7 can be prevented.

According to the method of manufacturing the semiconductor device of the first embodiment, the contact hole 13 is formed, the gate lifting polysilicon layer 14 is formed in the contact hole 13 by selective epitaxial growth, and then the contact plug 15 is formed by embedding a metal. For this reason, the silicide reaction does not reach the insulating film 7, and therefore the low-resistance contact plug 15 can be formed without an erosion breakdown of the insulating film 7.

### Second Embodiment

Hereinafter, a second embodiment of the present invention is explained.

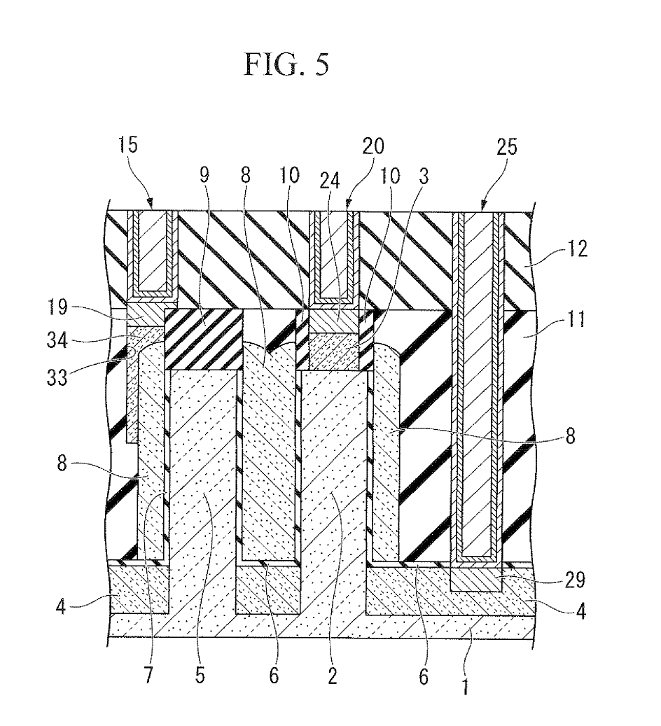

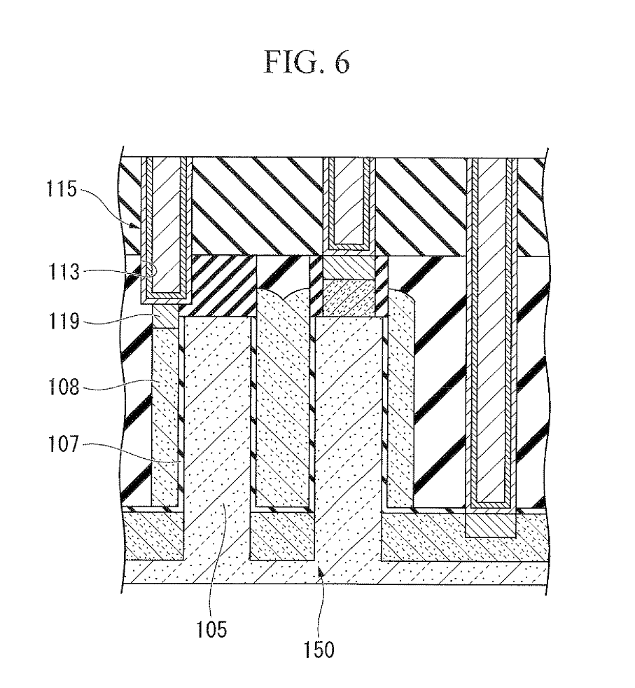

FIG. 5 is a cross-sectional view illustrating a semiconductor device according to the second embodiment.

Hereinafter, the structure of the semiconductor device according to the second embodiment is explained first.

The structures of a contact hole 33 and a gate-lifting polysilicon layer 34 in the semiconductor device of the second embodiment differ from those of the contact hole 13 and the gate-lifting polysilicon layer 14 of the first embodiment. Other structures of the semiconductor device of the second embodiment are the same as those of the first embodiment. For this reason, like reference numerals denote like elements between the first and second embodiments, and explanations thereof are omitted.

As shown in FIG. 5, the contact hole 33 penetrates the first and second inter-layer insulating films 11 and 12, and partially overlaps, if planarly viewed, the nitride film 9 and the gate electrode 8 without penetrating the nitride film 9 and the gate electrode 8. A level of a bottom surface of the contact hole 33 is lower than the level of the upper surface of the silicon pillar 5. However, the gate electrode 8 and the nitride film 9 prevent the contact hole 33 from directly contacting the gate insulating film 7.

A gate lifting polysilicon layer (embedded silicon layer) 34 is formed in the lower portion of the contact hole 33. The gate lifting polysilicon layer 34 is formed by filling polysilicon in the contact hole 33 from the level of the bottom surface of the contact hole 33 up to the level higher than the level of the upper surface of the gate electrode 8. The gate lifting polysilicon layer 34 is formed by selective epitaxial growth from the upper surface of the gate electrode 8 facing the contact hole 33. Even when the area of the gate electrode 8 shown through the contact hole 33 is increased as in the second embodiment, a similar effect to that in the first embodiment can be achieved.

Hereinafter, a method of manufacturing the semiconductor device according to the second embodiment is explained. Only a method of forming the contact hole 33 in the second embodiment differs from the method of the first embodiment. For this reason, explanations of other processes are omitted here.

The contact hole 33 is formed by known photolithography and dry etching (reactive ion etching). In the second embodiment, the reactive ion etching is carried out with high selectivity of the first and second inter-layer insulating films with respect to the gate electrode 8 and the nitride film 9. To meet the etching condition, for example, the reactive ion etching is carried out at pressure of 20 mTorr by providing C₄F₆ gas, O₂ gas, and Ar gas with the total flow volume of 250 sccm. Then, the gate lifting polysilicon layer 34 is formed by selective epitaxial growth, thus the semiconductor device of the second embodiment is formed.

It is apparent that the present invention is not limited to the above embodiments, but may be modified and changed without departing from the scope and spirit of the invention.

For example, although the silicon substrate is used as an example of the semiconductor substrate in the first and second embodiments, a substrate other than the silicon substrate may be used. Alternatively, a semiconductor layer may be formed on an insulating substrate such as a glass substrate, and then the semiconductor layer may be etched to form the first semiconductor pillar (and the second semiconductor pillar).

The layout of the conductive plugs and the wires is just an example, and various modifications can be made according to design requirements. Further, the transistor 50 may have an LDD (Lightly Doped Drain) structure.

As used herein, the following directional terms “forward, rearward, above, downward, vertical, horizontal, below, and transverse” as well as any other similar directional terms refer to those directions of a device equipped with the present invention. Accordingly, these terms, as utilized to describe the present invention should be interpreted relative to a device equipped with the present invention.

What is claimed is:

1. A semiconductor device, comprising:
a first semiconductor pillar extending upwardly from a semiconductor substrate;
a first gate insulating film covering side surfaces of the first semiconductor pillar;
a gate electrode covering the first gate insulating film, the first gate insulating film insulating the gate electrode from the first semiconductor pillar; and
a first contact partially overlapping, in plane view, the first semiconductor pillar and the gate electrode, the first contact comprising a silicon layer having a top level which is higher than a top level of the gate electrode.

2. The semiconductor device according to claim 1, wherein the first contact further comprises a first contact plug and a first silicide layer, the first silicide layer being between the first contact plug and the silicon layer.

3. The semiconductor device according to claim 2, wherein the first contact plug comprises a titanium layer, a titanium nitride layer, and a tungsten layer, the titanium nitride layer covering bottom and side surfaces of the titanium layer, and the tungsten layer covering bottom and side surfaces of the titanium nitride layer.

4. The semiconductor device according to claim 1, further comprising:
a second semiconductor pillar on the semiconductor substrate; and
a second gate insulating film covering side surfaces of the second semiconductor pillar,
wherein the gate electrode surrounds a combination of the first semiconductor pillar and the first gate insulating film, and a combination of the second semiconductor pillar and the second gate insulating film.

5. The semiconductor device according to claim 4, further comprising:
an insulating film extending over the semiconductor substrate, the insulating film extending around the first and second semiconductor pillars, and the insulating film extending under the gate electrode;
a first diffusion layer covering an upper surface of the second semiconductor pillar; and
a second diffusion layer in the semiconductor substrate, the second diffusion layer being covered by the insulating film.

6. The semiconductor device according to claim 5, further comprising:
a second contact over the first diffusion layer, the second contact comprising a second contact plug and a second silicide layer, the second silicide layer being disposed between the second contact plug and the first diffusion layer.

7. The semiconductor device according to claim 6, wherein the second contact plug comprises a titanium layer, a titanium nitride layer, and a tungsten layer, the titanium nitride layer covering bottom and side surfaces of the titanium layer, and the tungsten layer covering bottom and side surfaces of the titanium nitride layer.

8. The semiconductor device according to claim 1, further comprising:
a third contact extending upwardly from the second diffusion layer, the third contact comprising a third silicide layer and a third contact plug over the third silicide layer.

9. The semiconductor device according to claim 8, wherein the third contact plug comprises a titanium layer, a titanium nitride layer, and a tungsten layer, the titanium nitride layer covering bottom and side surfaces of the titanium layer, and the tungsten layer covering bottom and side surfaces of the titanium nitride layer.

10. The semiconductor device according to claim 1, wherein the first silicide layer is separated from the first semiconductor pillar and the first gate insulating film.

11. A method of manufacturing a semiconductor device, comprising:
forming first and second semiconductor pillars extending upwardly from a semiconductor substrate;
forming first and second gate insulating films covering side surfaces of the first and second semiconductor pillars, respectively;
forming a gate electrode surrounding a combination of the first semiconductor pillar and the first gate insulating film, and a combination of the second semiconductor pillar and the second gate insulating film;
forming a first contact that partially overlaps, in plane view, the first semiconductor pillar and the gate electrode; and
forming, in the first contact, a silicon layer having a top level which is higher than a top level of the gate electrode.

12. The method according to claim 10, further comprising:
forming a first contact plug and a first silicide layer in the first contact hole such that the first silicide layer is disposed between the first contact plug and the silicon layer, and the first silicide layer is separated from the first semiconductor pillar and the first gate insulating film.

13. The method according to claim 10, wherein forming the first silicide layer comprises carrying out epitaxial growth from the upper surface of the gate electrode.

14. The method according to claim 12, further comprising:
forming, in the first contact plug, a titanium layer, a titanium nitride layer, and a tungsten layer such that the titanium nitride layer covers bottom and side surfaces of the titanium layer, and the tungsten layer covers bottom and side surfaces of the titanium nitride layer.

15. The method according to claim 11, further comprising:
forming an insulating film extending over the semiconductor substrate, the insulating film extending around the first and second semiconductor pillars, and the insulating film extending under the gate electrode;
forming a first diffusion layer covering an upper surface of the second semiconductor pillar; and
forming, in the semiconductor substrate, a second diffusion layer covered by the insulating film.

16. The method according to claim 15, wherein forming the first diffusion layer comprises carrying out epitaxial growth from the upper surface of the second semiconductor pillar.

17. The method according to claim 15, further comprising:
forming a second contact over the first diffusion layer; and
forming a second contact plug and a second silicide layer in the second contact such that the second silicide layer is disposed between the second contact plug and the first diffusion layer.

18. The method according to claim 17, further comprising:
forming, in the second contact plug, a titanium layer, a titanium nitride layer, and a tungsten layer such that the titanium nitride layer covers bottom and side surfaces of the titanium layer, and the tungsten layer covers bottom and side surfaces of the titanium nitride layer.

19. The method according to claim 15, further comprising:
forming a third contact upwardly from the second diffusion layer; and
forming, in the third contact, a third silicide layer and a third contact plug over the third silicide layer.

20. The method according to claim 19, further comprising:
forming, in the third contact plug, a titanium layer, a titanium nitride layer, and a tungsten layer such that the titanium nitride layer covers bottom and side surfaces of the titanium layer, and the tungsten layer covers bottom and side surfaces of the titanium nitride layer.
